(19) United States
(12) Patent Application Publication
(10) Pub. No.: US 2006/0242533 A1
(43) Pub. Date: Oct. 26, 2006

(54) Method for updating check-node of low-density parity-check (LDPC) codes decoder and device using the same

(76) Inventors: Chen-Yi Lee, Hsinchu (TW); Chien-Ching Lin, Shueishang (TW); Kai-Li Lin, Shalu (TW); Hsie-Chia Chang, Keelung (TW)

Correspondence Address: BUCKNAM AND ARCHER, 1077 NORTHERN BOULEVARD, ROSLYN, NY, 11576, US

(21) Appl. No.: 11/221,193

(22) Filed: Sep. 7, 2005

(30) Foreign Application Priority Data
Apr. 21, 2005 (TW) 094112662

(51) Int. Cl. H03M 13/00

(52) U.S. Cl. 714/758

(57) ABSTRACT

The invention provides a method for updating check-node of low-density parity-check (LDPC) codes decoder. The method comprises the following steps: First of all, sort all data that are input into the check-node of LDPC codes decoder to find a minimum absolute value and a second minimum absolute value. Secondly, compare each of all the data to both of the minimum absolute value. If the compared data is equivalent to the current minimum absolute value, the compared data is updated by the secondary minimum absolute value. Otherwise, the compared data is updated by the minimum absolute value.

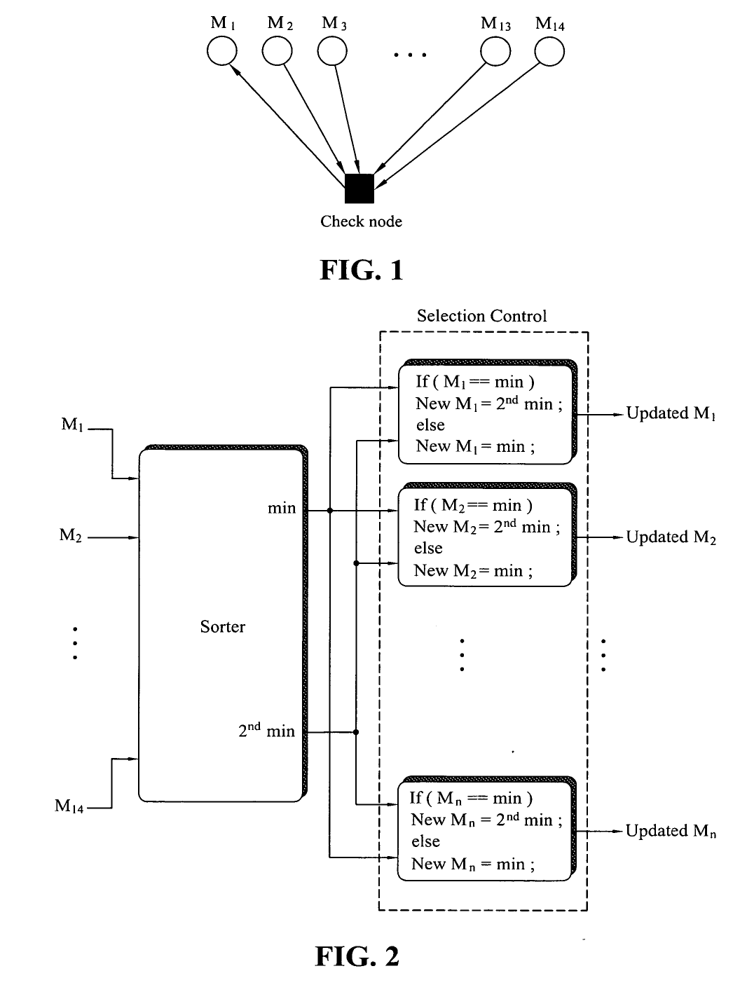

### FIELD OF THE INVENTION

The invention provides a method and an apparatus for updating the check-node of Low-Density Parity-Check (LDPC) codes decoder. Particularly, it also provides a method and an apparatus applicable to reduce calculation load and the complexity level in a high-speed communication system that utilizes the updating check-node of the LDPC codes decoder.

### BACKGROUND OF THE INVENTION

Low-Density Parity-Check (LDPC) algorithm is a high-efficient and high-speed technology applied in communication channel coding. In the future, data processing speed in communication could reach at the rate of 1 billion bits a second (Gb/s). Because the powerful error correction of the LDPC decoding could approach the Shannon Limit, the LDPC will be applied extensively in the future. Because the level of operation parallelism of the LDPC algorithm is high, the speed for processing communication data could reach as high as 1,000 trillion bits per second and above.

It is generally known that the LDPC codes decoder includes the operation on the check-node, which is a very complicated operation. In a high-speed communication system, the decoding speed of the LDPC codes decoder heavily depends on the data updating speed on the check-node. In the conventional application methods, to implement the complicated calculation in updating every single check-node, usually the multiple levels of look-up tables, summers or multiple comparators are employed. From the viewpoint of hardware, the increase in complexity level of hardware from these methods usually will automatically decrease the calculation speed in performance and increase the hardware cost.

On the invention of “Method and apparatus for decoding on the general codes on probability dependency graphs” on Mar. 25, 2003 under the U.S. patent right no.: U.S. Pat. No. 6,539,367 B1 by Blanksby illustrated a data updating scheme of a decoder, which basically applied the combination of look-up table and summer. However, as stated earlier, the scheme increases the hardware cost and slows down the process speed. Additionally, on the invention of “Method and apparatus for decoding LDPC codes” on Oct. 14, 2003 under the U.S. patent right no.: U.S. 6,633,856 B2 by Richardson illustrated a complete LDPC codes decoder scheme. However, it did not mention the actual data updating method at the check-nodes.

Therefore, to solve the difficulty in the highly complicated operation scheme and to increase the operation speed on the LDPC codes decoding, it becomes necessary that a new technology of updating data on the check-node for the LDPC be developed, which should also be competitive and cost-efficient compared to other technologies.

### SUMMARY OF THE INVENTION

Based on the known technological drawbacks, the invention is to provide a method and an apparatus for updating check-node data of low-density parity-check (LDPC) codes decoder, which is also able to reduce calculation load and complexity level; so it can provide high calculation power and low complexity level as required in the high-speed communication applications.

To achieve the aforementioned goals, the invention is able to provide a method for updating check-node data of low-density parity-check (LDPC) codes decoder, which comprises the following steps: sort all the data input to the check-node of the LDPC codes decoder to obtain the minimum absolute value and the second minimum absolute value; and compare each of all data to the minimum absolute value; if the compared data is equivalent to the current minimum absolute value, the compared data is updated by the secondary minimum absolute value. Otherwise, the compared data is updated by the minimum absolute value.

### DETAILED DESCRIPTION OF THE PREFERRED EMBODIMENTS

Please refer to the attached drawings to see the preferred embodiments of the invention. Although there are only 14 input ports that are input into the check-node, the invention in not only limited to the number; instead, it applies to an embodiment of any number.

Refer to the Drawing 1, it demonstrates the operation of the data updating of the check-node of the invention, where Ml, M2 . . . and M14 represent the message nodes. According to the invention, using the min-sum algorithm in LDPC can simplify the complicated hyper-tangent operation into searching for the direction of the minimum value to determine whether to update the data on the check-node. Furthermore, the invention uses the row operation in manipulating the data array of check-node, which needs only find out the minimum value and the second minimum value to update the data of entire row data simultaneously instead of employing the conventional technologies of updating the data of every single check-node in a row separately using look-up tables and summers, which is fairly complicated. As shown in the drawing 1, it clearly shows that the concept of the data updating apparatus of check-node; namely, using the data from message node M2 to M14 to update the data of Ml, using the data of message node M1, M3 to M14 to update the data of M2 (not shown on the drawing) . . . etc. Thus, the invention can be applied to simplify the implementation and the circuitry of the LDPC codes decoder on the baseband processor in a high-speed communication system. According to the test results from our lab, only using 0.18 micron fabrication process can achieve the data rate as high as 3.33 Gb/s.

The method of data update on the check-node of LDPC codes decoder used in the invention is to first search for the minimum value and the second minimum value that input to the check node, then use the searched two values to update the current values on check-node. Therefore, a preferred embodiment of the invention to update the data of check-node of LDPC comprises 2 major steps: First of all, sort all data that are input into the check-node of LDPC codes decoder to find a minimum absolute value and a second minimum absolute value, where the all data include an array of data inputs from every individual message check-node (namely, M1,M2 . . . and M14). Secondly, compare each of all the data to the minimum absolute value; if the compared data is equivalent to the current minimum absolute value, the compared data is updated by the secondary minimum absolute value. Otherwise, the compared data is updated by the minimum absolute value.

As shown on the drawing 2, the block diagram shows a rough scheme of a preferred embodiment of the invention about the data update on LDPC coders decoder. Basically, the invention about the apparatus of the data update on check-node comprises a sorter 1 and a comparator 2. As shown on the drawing, the sorter is used to sort all data which are input to the check-node of LDPC codes decoder to find the minimum absolute value and the second minimum absolute value. And the comparator is used to compare every individual data that is input to the check-node with the current minimum value and the current second minimum value to determine which data in the row of a message node to update.

As stated above, the invention illustrates a new scheme to update the data on a check-node to lower the hardware requirements. The invention uses the mini-sum algorithm of LDPC codes, and the check-node update unit comprises 2 components: 1-bit sign-multiplication (SM) and the compare-selection (CS) for all input data. Compared to those known technologies like LLR-SPA algorithm, which employs look-up tables to update the check-node data, the mini-sum algorithm of the invention to update check-node data is able to reduce the circuitry complexity significantly. Meanwhile, the SM and CS scheme of the invention can update all data inputs to the check-node simultaneously, which accelerates the calculation, and thus meets the requirements for the high-speed communication applications.

As stated above, we have illustrated a preferred embodiment of the invention. However, what should be understood is that the example is only descriptive instead of restrictive. The skilled who are familiar with the technology should also understand that many variations and modifications could be achieved without violating the essence and the claims of the invention.

### ILLUSTRATIVE DESCRIPTION OF THE INVENTION

The invention employs the descriptive but restrictive drawings to illustrate a preferred embodiment of the invention, where the arrow heads indicate the major directions of control and data flow instead of the direction only:

The drawing 1 shows the apparatus for the data update on check-node of the invention. And

The drawing 2 is the block diagram that shows a rough scheme of a preferred embodiment of the invention, where the scheme uses the apparatus for the data update on check-node of the LDPC coders decoder.

List of Reference Numberals

1 Sorter
2 Comparator

What is claimed is:

1. A method for updating the data on check-node of the LDPC coders decoder, which comprises:
sorting all data inputs to the check-node of LDPC to find a minimum absolute value and second minimum value; and
comparing every individual data input to the check-node with the current minimum absolute value; if the compared data is equivalent to the current minimum absolute value, the compared data is updated by the secondary minimum absolute value. Otherwise, the compared data is updated by the minimum absolute value.

2. An apparatus for updating the data on check-node of the LDPC coders decoder, which comprises:
a sorter for sorting all data inputs to the check-node of LDPC to find a minimum absolute value and second minimum value; and
a comparator for comparing every individual data input to the check-node with the current minimum absolute value; if the compared data is equivalent to the current minimum absolute value, the compared data is updated by the secondary minimum absolute value. Otherwise, the compared data is updated by the minimum absolute value.
